(19) United States
(12) Patent Application Publication
(10) Pub. No.: US 2022/0200117 A1
(43) Pub. Date: Jun. 23, 2022

(54) TRANSMISSION DEVICE

(71) Applicant: STMicroelectronics (Grenoble 2) SAS, Grenoble (FR)

(72) Inventors: Ludovic FOURNEAUD, Saint Vincent de Mercuze (FR); Gregory BOUTELOUP, Venon (FR); Jerome LOPEZ, Saint Jean de Moirans (FR)

(73) Assignee: STMicroelectronics (Grenoble 2) SAS, Grenoble (FR)

(21) Appl. No.: 17/552,595

(22) Filed: Dec. 16, 2021

(30) Foreign Application Priority Data
Dec. 22, 2020 (FR) 2013949

(51) Int. Cl. H01P 3/08; H05K 1/02; H05K 1/11; H05K 1/03

(52) U.S. Cl. CPC H01P 3/081; H05K 1/0393; H05K 1/118; H05K 1/0237

(57) ABSTRACT

A device for transmission of at least one high-frequency signal includes at least one first electrically-conductive track formed inside and/or on top of a flexible substrate.

### PRIORITY CLAIM

This application claims the priority benefit of French Application for Patent No. 2013949, filed on Dec. 22, 2020, the content of which is hereby incorporated by reference in its entirety to the maximum extent allowable by law.

### TECHNICAL FIELD

The present disclosure generally concerns the transmission of electric signals between a plurality of elements, such as electronic devices and/or substrates. The present disclosure concerns, in particular, the transmission of high-frequency signals.

### BACKGROUND

The use of high-frequency signals is currently a significant issue for the industry. Indeed, such signals are particularly used for the communication within an electronic system, or between a plurality of electronic systems.

The transmission of high-frequency signals imposes certain constraints on the design of complex electronic systems. Indeed, high-frequency signals are sensitive to different phenomena likely to alter them, such as electromagnetic coupling phenomena, power loss phenomena, etc. High-frequency signals are particularly sensitive to a specific type of electromagnetic coupling, where radiative noise phenomena is likely to occur when two high-frequency signals are transmitted by spatially close transmission devices.

It would be desirable to be able to at least partly improve certain aspects of the transmission of high-frequency signals.

There is a need for a higher-performance high-frequency signal transmission device.

There is a need for a high-frequency signal transmission device more resistant to parasitic electromagnetic coupling phenomena.

There is a need for a high-frequency signal transmission device more resistant to power loss phenomena.

There is a need for a high-frequency signal transmission device more resistant to radiative noise phenomena.

There is a need for a high-frequency signal transmission device adapted to the transmission of signals within an electronic system.

More particularly, there is a need for a high-frequency signal transmission device adapted to the transmission of signals between electronic chips, or between an electronic chip and a substrate during their assembly.

### SUMMARY

An embodiment overcomes all or part of the disadvantages of known high-frequency signal transmission devices.

An embodiment provides a device for transmitting at least one high-frequency signal comprising at least one first electrically-conductive track formed inside and/or on top of a flexible substrate.

According to an embodiment, the flexible substrate is made of a material which, for a thickness in the range from 20 to 500 μm, and for a length shorter than 2 mm, has a permittivity is in the range from 1 to 10 F·m⁻¹.

According to an embodiment, the material of the flexible substrate is selected from the following group: polytetrafluoroethylene (also known under trade name Teflon, or under name PTFE) and its derivatives and compounds, fluoropolymers such as perfluoroalkoxy (also known under name PFA), fluorinated ethylene propylene (also known under name FEP), polychlorotrifluoroethylene (also known under name PCTFE), ethylene tetrafluoroethylene (also known under name ETFE), silicon oxide such as glass and its compounds, or materials based on fiberglass, ceramics such as alumina and its compounds, resins such as epoxy resin, such as that known under trade name Epoxy FR4, polymers such as polyetheretherketone (also known under name PEEK), polyimides such as a flexible copper clad laminate (also known under name FCCL) and mixtures and compounds of the previously-mentioned elements.

According to an embodiment, the high-frequency signals have a frequency in the range from 30 MHz to 300 GHz.

According to an embodiment, said first track at least partially covers a surface of said flexible substrate.

According to an embodiment, said first track entirely covers a surface of said flexible substrate.

According to an embodiment, said first track is a metal track.

According to an embodiment, the metal track is made of a metal alloy comprising copper, aluminum, tin, nickel, palladium, tungsten, gold, or silver, or only made of gold.

According to an embodiment, said first track is a waveguide.

According to an embodiment, the device comprises at least one second conductive track.

According to an embodiment, the second conductive track is adapted to transmitting a reference signal, for example, the ground.

Another embodiment provides an electronic system comprising a previously-described transmission device.

According to an embodiment, the system further comprises at least one first element having at least one first contact arranged thereon, and at least one second element having at least one second contact arranged thereon, said transmission device being arranged to couple said at least one first contact to said at least one second contact.

According to an embodiment, said at least one first element is an electronic device or a substrate, and said at least one second element is an electronic device or a substrate.

According to an embodiment, the system further comprises at least one third element having at least one third contact arranged thereon, said transmission device being adapted to coupling the first, second, and their contacts together.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 schematically shows a perspective view of an embodiment of an electronic system;

FIGS. 2(a)-2(f) show six cross-section views of embodiments of transmission devices of the system of FIG. 1;

FIGS. 3(a)-3(b) show two partial top views of embodiments of transmission devices of the system of FIG. 1;

FIGS. 4(a)-4(b) show two side views of embodiments of systems of FIG. 1; and

FIG. 5 schematically shows in the form of blocks a top view of a step of a method of manufacturing a transmission device of the system of FIG. 1.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the different protocols used for the transmission of high-frequency signals are not detailed in the description. Indeed, the described embodiments are compatible with most known high-frequency signal transmission protocols.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following description, the adjective “conductive” designates, by default, the electric conductivity of an element and not its thermal conductivity.

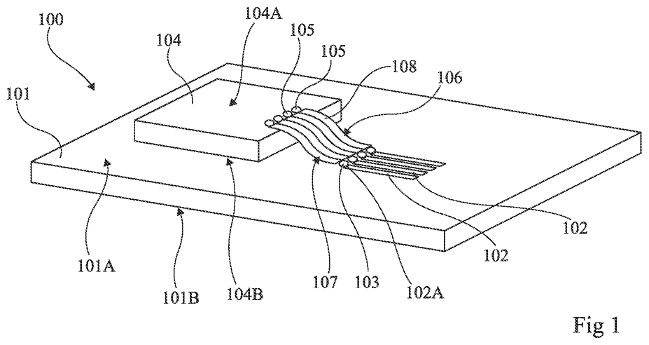

FIG. 1 is a simplified perspective view of an embodiment of an electronic system 100. Electronic system 100 is, more particularly, an electronic chip assembled on a substrate.

Electronic system 100 comprises a substrate 101. Substrate 101 may be a solid substrate, for example, silicon and/or germanium, a substrate of silicon on insulator (SOI) type, a laminated substrate comprising a plurality of dielectric material layers, a resin substrate, a ceramic substrate, or a plastic substrate.

Substrate 101 comprises one or a plurality of conductive tracks 102 positioned on its upper surface or front side 101A. Conductive track(s) 102 enable to couple, or to connect, contacts 103, vias (not shown in FIG. 1), etc., formed inside and/or on top of the front surface 101A of substrate 101. According to an embodiment, each conductive track 102 comprises at least one end 102A coupled to a contact 103, or connection pad, arranged on the front side 101A of substrate 101. Conductive track(s) 102 are, for example, metal tracks. According to an example, conductive tracks 102 are made of a metal or a metal alloy comprising copper, gold, or silver. According to another example, conductive tracks 102 are waveguides. In FIG. 1, according to an embodiment, four conductive tracks 102 arranged parallel to one another are shown, each having its end 102A connected to a contact 103. The four contacts 103 shown in FIG. 1 are aligned.

Substrate 101 may comprise one or a plurality of electronic components, not shown in FIG. 1, formed from its upper surface 101A or from its lower surface, or back side, 101B, it is then spoken of electronic components embedded in substrate 101. According to an example, certain contacts of these electronic components may be electrically coupled to one another via conductive tracks 102.

Electronic system 100 further comprises an electronic device 104 assembled on the front side 101A of substrate 101. Device 104 comprises an upper surface, or front side, 104A, and a lower surface, or back side, 104B. Back side 104B is fastened to the front side 101A of substrate 101, for example, by a bonding or soldering method. Device 104 may be an electronic component, an assembly of electronic components, a printed circuit, an electronic chip, etc. Device 104 may, for example, be surrounded with a protective package.

Device 104 further comprises one or a plurality of contacts 105 positioned on its front side 104A. In FIG. 1, according to an embodiment, four contacts 105 aligned with one another are shown. According to an embodiment, contact(s) 105 are, for example, metal connection areas, such as soldering areas or metal pads. According to an example, contacts 105 are made of a metal or of a metal alloy comprising copper or gold. It will be understood by those skilled in the art that device 104 may further comprise contacts formed from its back side 104B.

According to an embodiment, substrate 101 and device 104 are adapted to use high-frequency signals. The high-frequency signals are signals having a frequency in the range from 30 MHz to 300 GHz. Thus, the contacts 103 and the conductive tracks 102 of substrate 101, and the contacts 105 of device 104 are sized and positioned to be able to transmit high-frequency signals. In particular, contacts 103, respectively electronic tracks 102, contacts 105, are sized to allow a good transmission of high-frequency signals. More particularly, the materials used to form contacts 103, electronic tracks 102, contacts 105, and their dimensions are adapted to the transmission of high-frequency signals. According to an example, contacts 103, respectively electronic tracks 102, contacts 105, are sufficiently spaced apart from one another to avoid, among others, electromagnetic coupling phenomena, such as radiative noise phenomena, etc.

Electronic system 100 further comprises an embodiment of a high-frequency signal transmission device 106 coupling the contacts 103 of substrate 101 to the contacts 105 of substrate 104. Device 106 is formed from a flexible substrate 107, inside and/or on top of which are positioned conductive tracks 108. According to an example, device 106 has, in top view, a substantially rectangular shape, for example, square or rectangular with rounded angles.

According to an embodiment, flexible substrate 107 is made of a dielectric material with a good flexibility-thickness-electric permittivity compromise. More particularly, for a thickness in the range from 20 to 500 μm, for example, in the order of 200 μm, this material is flexible for a short length of substrate 107, that is, for a length shorter than 2 mm. Further, the permittivity of the material is in the range from 1 to 10 F·m⁻¹, for example from 1 to 5 F·m⁻¹. Materials capable of being used to form substrate 107 may be selected from the following group: polytetrafluoroethylene (also known under trade name Teflon, or under name PTFE) and its derivatives and compounds, fluoropolymers such as perfluoroalkoxy (also known under name PFA), fluorinated ethylene propylene (also known under name FEP), polychlorotrifluoroethylene (also known under name PCTFE), ethylene tetrafluoroethylene (also known under name ETFE), silicon oxide such as glass and its compounds, or materials based on fiberglass, ceramics such as alumina and its compounds, resins such as epoxy resin, such as that known under trade name Epoxy FR4, polymers such as polyetheretherketone (also known under name PEEK), polyimides such as a flexible copper clad laminate (also known under name FCCL) and mixtures and compounds of the previously-mentioned elements.

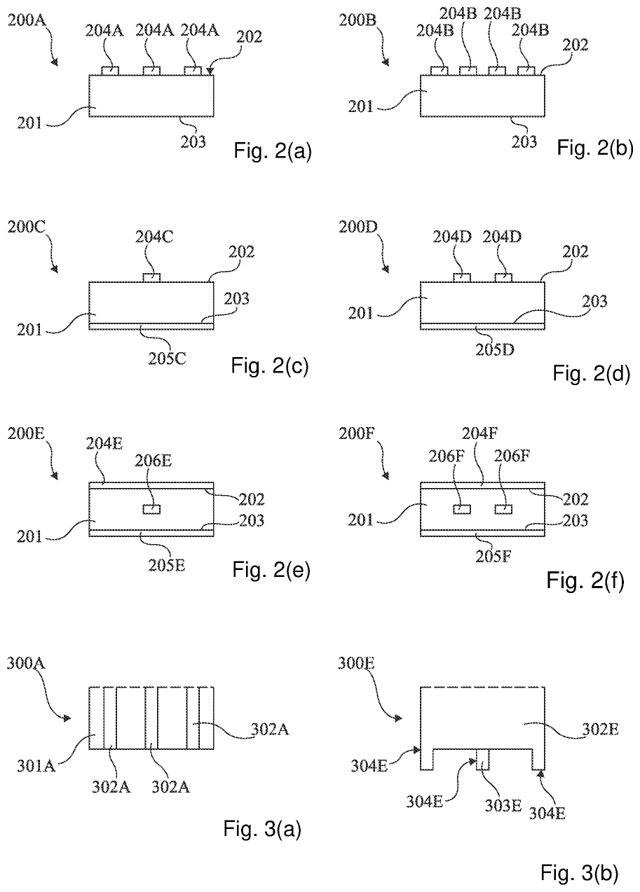

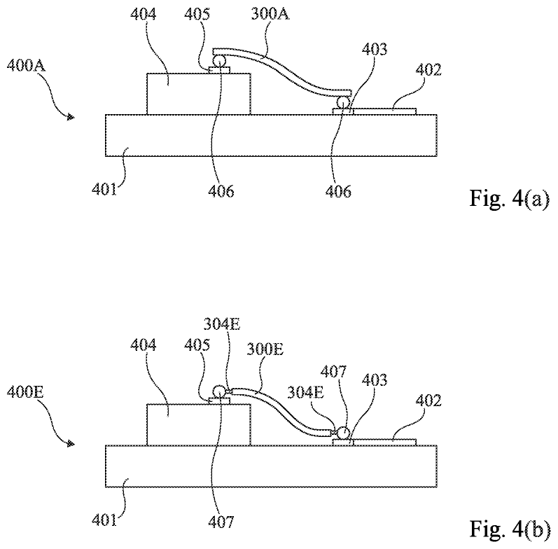

Device 106 may comprise as many conductive tracks 108 as necessary. In FIG. 1, device 106 comprises four conductive tracks 108 arranged parallel to one another. Each conductive track 108 couples a contact 103 of substrate 101 to a contact 105 of electronic device 104. Conductive track(s) 102 are, for example, metal tracks. According to an example, conductive tracks 102 are made of a metal or of a metal alloy comprising copper, aluminum, tin, nickel, palladium, tungsten, gold, or silver. According to another example, conductive tracks 102 are waveguides. Examples of a device 106 comprising from two to four conductive tracks are described in relation with FIG. 2. Further, practical examples of means of connection of tracks 108 to contacts 103 and 105 are described in relation with FIGS. 3 and 4.

The dimensions of transmission device 106 are determined by taking into account a plurality of criteria, among which include: the number of conductive tracks 108 that it contains, as well as their layout; the total impedance of device 106; and the bulk and the layout of electronic device 104 of substrate 101.

Indeed, it is preferable for transmission device 106 to have an impedance as close as possible to the output impedance of device 104, that is, the impedance at the level of contacts 105, and to the output impedance of substrate 101, that is, the impedance at the level of contacts 103.

An advantage of the use of a transmission device of the type of device 106 is that it enables to transmit a plurality of high-frequency signals with a single device. Indeed, the connection methods adapted to high-frequency signals known to date, such as wire bonding, only allow the transmission of a single signal at a time since they only allow the connection of two contacts at a time.

Those skilled in the art will understand that a high-frequency transmission device of the type of device 106 may also be used between two electronic devices of the type of device 104 assembled on a same substrate, or on different substrates, or may also be used between two different substrates, or even between contacts of a same substrate.

FIGS. 2(a)-2(f) shown six cross-section views of embodiments of high-frequency signal transmission devices of the type of the transmission device 106 described in relation with FIG. 1.

FIG. 2(a) shows a high-frequency signal transmission device 200A, of the type of the device 106 described in relation with FIG. 1, comprising a substrate 201, of the type of the substrate 107 described in relation with FIG. 1. Substrate 201 comprises an upper surface, or front side, 202, and a lower surface, or back side, 203. Device 200A further comprises three conductive tracks 204A of the type of the conductive tracks 108 described in relation with FIG. 1. Conductive tracks 204A are formed on the front side 202 of substrate 202. According to the example of FIG. 2(a), conductive tracks 204A are positioned side by side and parallel to one another. Such a configuration is, for example, compatible with the use of coplanar waveguides as high-frequency signal transmission means. According to an example, the central conductive track 204A may transmit a high-frequency signal, and the lateral conductive tracks 204A may transmit a reference signal, for example, the ground.

FIG. 2(b) shows a high-frequency signal transmission device 200B similar to the device 200A of FIG. 2(a), comprising substrate 201 and conductive tracks 204B arranged on the front side 202 of substrate 201. Conversely to device 200A, device 200B comprises four conductive tracks 204B arranged side by side and parallel to one another on substrate 201. Further, as for device 200A, such a configuration is, for example, compatible with the use of coplanar waveguides (CPW) as high-frequency signal transmission means, and more particularly with the use of differential coplanar waveguides. According to an example, a first central conductive track 204B may transmit a high-frequency signal, a second central conductive track 204B may transmit the complement of the high-frequency signal, and the lateral conductive tracks 204B may transmit a reference signal, for example, the ground.

FIG. 2(c) shows a high-frequency signal transmission device 200C, of the type of the device 106 described in relation with FIG. 1, comprising the substrate 201 of FIGS. 2(a) and 2(b). Device 200C further comprises two conductive tracks 204C and 205C of the type of the conductive tracks 108 described in relation with FIG. 1. Conductive track 204C is positioned on the front side 202 of substrate 201. Conductive track 204C has a width smaller than the width of substrate 201. Conductive track 205C is positioned on the back side 203 of substrate 201. According to an embodiment, conductive track 205C covers most of, or even the entire width of back side 203 of substrate 201. Such a configuration is, for example, compatible with the use of a microstrip-type structure used as high-frequency signal transmission means. According to an example, conductive track 204C transmits a high-frequency signal, and conductive track 205C transmits a reference signal, for example, the ground.

FIG. 2(d) shows a high-frequency signal transmission device 200D similar to the device 200C of FIG. 2(c), comprising substrate 201 and conductive tracks 204D arranged on the front side 202 of substrate 201, and a conductive track 205D arranged on the back side 203 of substrate 201. Conversely to device 200C, device 200D comprises two conductive tracks 204D arranged side by side and parallel to one another on the front surface 202 of substrate 201. However, as in device 200C, conductive track 205D extends over most of or even the entire width of the back side 203 of substrate 201. Further, as for device 200C, such a configuration is, for example, compatible with the use of a microstrip-type structure used as high-frequency signal transmission means, and more particularly a differential microstrip type structure. According to an example, a first conductive track 204D transmits a high-frequency signal, and second conductive track 204D transmits the complement of the high-frequency signal, and conductive track 205D transmits a reference signal, for example, the ground.

FIG. 2(e) shows a high-frequency signal transmission device 200E, of the type of the device 106 described in relation with FIG. 1, comprising the substrate 201 of FIGS. 2(a) to 2(d). Device 200E further comprises three conductive tracks 204E, 205E, and 206E of the type of the conductive tracks 108 described in relation with FIG. 1. Conductive track 204E is positioned on the front side 202 of substrate 201. According to an embodiment, conductive track 204E covers most of, or event all of, the width of the front side 202 of substrate 201. Conductive track 205E is positioned on the back side 203 of substrate 201. According to an embodiment, conductive track 205E covers most of, or even all of, the width of back side 203 of substrate 201. Conductive track 206E is buried in substrate 201. According to an example, the width of conductive track 206E is smaller than the width of substrate 201. Such a configuration is, for example, compatible with the use of a strip line-type conductive structure used as high-frequency signal transmission means. According to an example, conductive track 206E transmits a high-frequency signal, and conductive tracks 204E and 205E transmit a reference signal, for example, the ground.

FIG. 2(f) shows a high-frequency signal transmission device 200F similar to the device 200E of FIG. 2(e), comprising substrate 201 and a conductive track 204F arranged on the front side 202 of substrate 201, a conductive track 205F arranged on the back side 203 of substrate 201, and two conductive tracks 206F buried in substrate 201. Conversely to device 200E, device 200F comprises two conductive tracks 206F arranged side by side and parallel to each other, and buried in substrate 201. However, as in device 200E, conductive track 204F, respectively conductive track 205F, extends over most of or even the entire width of the front side 202, respectively the back side 203 of substrate 201. Further, as for device 200E, such a configuration is, for example, compatible with the use of a structure of strip line type used as high-frequency signal transmission means, and more particularly a structure of differential strip line type. According to an example, a first conductive track 206F transmits a high-frequency signal, and second conductive track 206F transmits the complement of the high-frequency signal, and conductive tracks 204F and 205F transmit a reference signal, for example, the ground.

Those skilled in the art will understand that other configurations of high-frequency signal transmission devices can be envisaged, by varying the number of conductive tracks arranged on the front and back sides of the substrate, and/or buried in the substrate. The width of the conductive tracks is also adjustable.

An advantage of transmission device 106, and of transmission devices 200A to 200F is that they are compatible with different already-existing high-frequency signal transmission means. Thus, devices 106, and 200A to 200F are compatible with already-existing electronic substrates and devices.

Another advantage of these devices is that they enable to control internal coupling phenomena and to limit radiative noise.

FIGS. 3(a)-3(b) shows two top views of devices of the type of the device 106 described in relation with FIG. 1.

FIG. 3(a) more particularly illustrates an end of a device 300A of the type of the device 200A described in relation with FIG. 2(a). Like device 200A, device 300A comprises a substrate 301A having three conductive tracks 302A formed thereon. Conductive tracks 302A have their end flush with the end of substrate 301A.

FIG. 3(b) more particularly illustrates an end of a device 300E of the type of the device 200E described in relation with FIG. 2(e). Like device 200E, device 300E comprises a substrate, not shown in FIG. 3(b), a conductive track 302E arranged on the upper surface of the substrate, and a conductive track 303E buried in the substrate. Conductive tracks 302E and 303E each comprise, at their end, an extension 304E protruding from the substrate. Extensions 304E allow the connection of conductive tracks 302E to contacts. Examples of methods of connection of devices 300A and 300E are described in relation with FIGS. 4(a) and 4(b).

FIGS. 4(a)-4(b) shows two side views of electronic systems of the type of the electronic system 100 described in relation with FIG. 1.

FIG. 4(a) shows an electronic system 400A similar to the electronic system 100 of FIG. 1. Thus, system 400A comprises: a substrate 401, of the type of the substrate 101 described in relation with FIG. 1, on which is arranged at least one electronic track 402 having an end coupled to a contact 403; an electronic device 404, of the type of the electronic device 104 described in relation with FIG. 1, assembled on substrate 401, and comprising at least one contact 405 on its upper surface; and transmission device 300A.

Transmission device 300A is arranged to couple contact 403 of substrate 403 to contact 405 of device 404. The two ends of device 300A are bonded to contacts 403 and 405. According to an embodiment, the ends of device 300A are soldered to contacts 403 and 405. More particularly, one of the conductive tracks 302A of device 300A has one of its ends soldered to contact 403, and its other end soldered to contact 405. To achieve this, a metal ball 406 formed by a technique related to wire connection techniques may be used. Indeed, metal ball 406 may be made malleable by a method using ultrasound waves, and then be crushed onto contact 403 or 405, or onto the conductive track 302A of device 300A. Metal ball 406 is, for example, made of a metal alloy comprising copper, aluminum, tin, nickel, palladium, tungsten, gold, or silver, or only made of gold. According to an example, metal ball 406 is deposited by a reflow soldering technique.

FIG. 4(b) shows an electronic system 400E similar to the electronic system 400A of FIG. 4(a). The elements common to devices 400A and 400E are not described again, and only their differences are highlighted hereafter. Conversely to device 400A, device 400E uses the device 300E described in relation with FIG. 3(b) to connect device 404 to substrate 401.

More particularly, as previously mentioned, the conductive tracks 302E of device 300E comprise extensions 304E at their end to ease their connection to contacts. According to an embodiment, one of the conductive tracks 302 of device 300E has one of its ends soldered to contact 403, and its other end soldered to contact 405. More particularly, the extensions 304E of said conductive track are soldered to contacts 403 and 405 by using a solder ball 407. The solder ball is, for example, made of an alloy of metals, for example comprising zinc, copper, silver, etc.

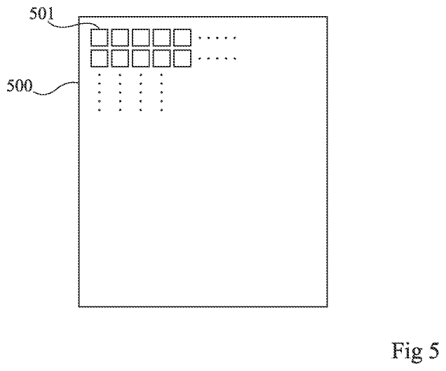

FIG. 5 is a simplified top view in the form of blocks of a plate 500 on top and inside of which are formed a plurality of high-frequency signal transmission devices 501 of the type of the devices 106, described in relation with FIG. 1, of the devices 200A to 200F described in relation with FIG. 2, or of the devices 300A to 300E described in relation with FIG. 3.

Plate 500 is a substrate plate made of the same material as the flexible substrate used to form devices 106, 200A to 200F, 300A, and 300F. An advantage of devices 501 is that they may be manufactured in series on plate 500, and then be individualized by cutting of plate 500. This allows a greater efficiency of the method of manufacturing these devices.

Various embodiments and variants have been described. Those skilled in the art will understand that certain features of these various embodiments and variants may be combined, and other variants will occur to those skilled in the art. In particular, the high-frequency signal transmission devices have been described as enabling to couple two elements, an element here being a substrate or an electronic device, but those skilled in the art may adapt the shape of the transmission device so that it enables to couple more than two elements. Thus, according to an example, the transmission device may have a Y shape to enable to couple three elements (i.e., a first leg of the Y shape for device 106 is connected to a first device 104 or tracks 102, a second leg of the Y shape for device 106 is connected to a second device 104 or tracks 102, and a third leg of the Y shape for device 106 is connected to a third device 104 or tracks 102), or a star shape to enable to couple four or more than four elements.

Finally, the practical implementation of the described embodiments and variations is within the abilities of those skilled in the art based on the functional indications given hereabove.

1. A device of transmission of at least one high-frequency signal, comprising:
a flexible substrate having a top; and
at least one first electrically-conductive track formed inside and/or at the top of the flexible substrate.

2. The device according to claim 1, wherein the flexible substrate has a thickness in a range from 20 to 500 μm and a length smaller than 2 mm and which is made of a material having a permittivity in a range from 1 to 10 F·m−1.

3. The device according to claim 2, wherein the material of the flexible substrate is selected from group consisting of: polytetrafluoroethylene and its derivatives and compounds, fluoropolymers including perfluoroalkoxy, fluorinated ethylene propylene, polychlorotrifluoroethylene, ethylene tetrafluoroethylene, silicon oxide including glass and its compounds or materials based on fiberglass, ceramics including alumina and its compounds, resins including epoxy resin, polymers including polyetheretherketone, polyimides including a flexible copper clad laminate and mixtures and compounds of the previously-mentioned elements.

4. The device according to claim 1, wherein the high-frequency signals have a frequency in a range from 30 MHz to 300 GHz.

5. The device according to claim 1, wherein said at least one first electrically-conductive track at least partially covers a surface of said flexible substrate.

6. The device according to claim 5, wherein said at least one first electrically-conductive track entirely covers a surface of said flexible substrate.

7. The device according to claim 1, wherein said at least one first electrically-conductive track is a metal track.

8. The device according to claim 7, wherein the metal track is made of a metal alloy comprising a material selected from the group consisting of: copper, aluminum, tin, nickel, palladium, tungsten, gold, or silver, or made of gold.

9. The device according to claim 1, wherein said at least one first electrically-conductive track is a waveguide.

10. The device according to claim 1, further comprising at least one second electrically-conductive track.

11. The device according to claim 10, wherein the at least one second electrically-conductive track is configured to support a reference signal such as ground.

12. The device according to claim 1, comprising the first electrically-conductive track and a second electrically-conductive track at the top of the flexible substrate, with the first electrically-conductive track carrying a high frequency signal and the second electrically-conductive track carrying a ground reference.

13. The device according to claim 1, comprising the first electrically-conductive track inside the flexible substrate and a second electrically-conductive track at a bottom of the flexible substrate, with the first electrically-conductive track carrying a high frequency signal and the second electrically-conductive track carrying a ground reference.

14. The device according to claim 1, comprising the first electrically-conductive track at the top of the flexible substrate and a second electrically-conductive track at a bottom of the flexible substrate, with the first electrically-conductive track carrying a high frequency signal and the second electrically-conductive track carrying a ground reference.

15. An electronic system, comprising a transmission device according to claim 1.

16. The system according to claim 15, further comprising at least one first element having at least one first contact arranged thereon, and at least one second element having at least one second contact arranged thereon, said transmission device being arranged to couple said at least one first electrically-conductive track to said at least one second contact.

17. The system according to claim 16, wherein said at least one first element is an electronic device or a substrate, and said at least one second element is an electronic device or a substrate.

18. The system according to claim 16, further comprising at least one third element having at least one third contact arranged thereon, said transmission device having a Y shape and configured to couple the first, second, and third contacts together.
